(19) United States
(12) Patent Application Publication
(10) Pub. No.: US 2023/0016704 A1
(43) Pub. Date: Jan. 19, 2023

(54) LAYOUT STRUCTURE OF ANTI-FUSE ARRAY

(71) Applicant: CHANGXIN MEMORY TECHNOLOGIES, INC., Hefei City (CN)

(72) Inventor: Lin WANG, Hefei City (CN)

(73) Assignee: CHANGXIN MEMORY TECHNOLOGIES, INC., Hefei City (CN)

(21) Appl. No.: 17/657,937

(22) Filed: Apr. 4, 2022

Related U.S. Application Data
(63) Continuation of application No. PCT/CN2021/117048, filed on Sep. 7, 2021.

(30) Foreign Application Priority Data
Jul. 13, 2021 (CN) 202110791627.3

(51) Int. Cl. H01L 23/525; H01L 29/06; H01L 27/02

(52) U.S. Cl. CPC H01L 23/5252; H01L 29/0607; H01L 27/0207; H01L 27/0248

(57) ABSTRACT

A layout structure of an anti-fuse array at least includes an array circuit area and a functional circuit area. The array circuit area is electrically connected with the functional circuit area. The functional circuit area is located on at least one side of the array circuit area, and at least one side of the array circuit area is located on an edge of the layout structure. The array circuit area includes an anti-fuse array composed of anti-fuse cells, and the array circuit area is configured to provide the anti-fuse cells under different column addresses to the functional circuit area. The functional circuit area is configured to fuse the anti-fuse cells under the different column addresses.

### CROSS-REFERENCE TO RELATED APPLICATIONS

This is a continuation of International Application No. PCT/CN2021/117048 filed on Sep. 7, 2021, which claims priority to Chinese Patent Application No. 202110791627.3 filed on Jul. 13, 2021. The disclosures of these applications are hereby incorporated by reference in their entirety.

### BACKGROUND

An anti-fuse device is a One Time Program (OTP) device, which is widely used in a Dynamic Random Access Memory (DRAM) and other memories. The anti-fuse device is a semiconductor device composed of two conductive layers and a dielectric layer between the conductive layers. Before programming, the conductive layers are separated by the dielectric layer, and two ends of an anti-fuse are in an open circuit. During programming (externally applied high voltage), the dielectric layer is broken down by high voltage, an electrical connection is formed between the conductive layers on both sides, and the anti-fuse is in a short circuit (fused). Such fusing is physically disposable, permanent and irreversible. The on state and the off state of the anti-fuse may represent logical values “0” and “1” respectively.

### SUMMARY

The embodiment of the disclosure relates, but is not limited, to a layout structure of an anti-fuse array.

The embodiment of the disclosure provides a layout structure of an anti-fuse array, which may at least include an array circuit area and a functional circuit area. The array circuit area is electrically connected with the functional circuit area. The functional circuit area is located on at least one side of the array circuit area, and at least one side of the array circuit area is located on the edge of the layout structure. The array circuit area may include an anti-fuse array composed of anti-fuse cells, and the array circuit area is configured to provide the anti-fuse cells under different column addresses to the functional circuit area. The functional circuit area is configured to fuse the anti-fuse cells under the different column addresses.

### BRIEF DESCRIPTION OF THE DRAWINGS

In the drawings (which are not necessarily drawn to scale), similar reference signs may describe similar parts in different views. Similar reference signs with different letter suffixes may represent different examples of similar parts. The drawings generally illustrate the various embodiments discussed herein by way of examples rather than limitation.

FIG. 1A is a circuit diagram of an anti-fuse array in some implementations.

FIG. 1B is a layout diagram of an anti-fuse array in some implementations.

FIG. 1C is another circuit diagram of an anti-fuse array in some implementations.

FIG. 1D is a schematic diagram of a layout structure of an anti-fuse array in some implementations.

FIG. 1E is a schematic diagram of signal transmission of an anti-fuse array in some implementations.

FIG. 2A is a first optional schematic structural diagram of a layout structure of an anti-fuse array provided in an embodiment of the disclosure.

FIG. 2B is a second optional schematic structural diagram of a layout structure of an anti-fuse array provided in an embodiment of the disclosure.

FIG. 2C is a third optional schematic structural diagram of a layout structure of an anti-fuse array provided in an embodiment of the disclosure.

FIG. 2D is a fourth optional schematic structural diagram of a layout structure of an anti-fuse array provided in an embodiment of the disclosure.

FIG. 3A is a first optional schematic diagram of a layout structure of an anti-fuse array provided in an embodiment of the disclosure.

FIG. 3B is a second optional schematic diagram of a layout structure of an anti-fuse array provided in an embodiment of the disclosure.

FIG. 3C is a third optional schematic diagram of a layout structure of an anti-fuse array provided in an embodiment of the disclosure.

FIG. 3D is a schematic structural diagram of a protection circuit cell provided in an embodiment of the disclosure.

FIG. 4A is another optional schematic diagram of a layout structure of an anti-fuse array provided in an embodiment of the disclosure.

FIG. 4B is yet another optional schematic diagram of a layout structure of an anti-fuse array provided in an embodiment of the disclosure.

### DETAILED DESCRIPTION

Exemplary implementation modes of the disclosure will be described below in more detail with reference to the drawings. Although the exemplary implementation modes of the disclosure are shown in the drawings, it should be understood that, the disclosure may be implemented in various forms and should not be limited by the specific implementation modes elaborated herein. On the contrary, these implementation modes are provided to enable a more thorough understanding of the disclosure and to fully convey the scope of the disclosure to those skilled in the art.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, not all of the features in the actual embodiments are described here, and the known functions and structures are not described in detail.

In the drawings, the dimensions of layers, areas and elements and their relative dimensions may be exaggerated for clarity. Throughout the description, the same reference signs represent the same elements.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers and/or parts may be described with terms first, second, third, etc., these elements, components, areas, layers and/or parts should not be limited by these terms. These terms are only used to distinguish one element, component, area, layer or part from another element, component, area, layer or part. Therefore, a first element, component, area, layer or part discussed below may be represented as a second element, component, area, layer or part without departing from the teaching of the disclosure. Moreover, when the second element, component, area, layer or part is discussed, it does not mean that the first element, component, area, layer or part must be present in the disclosure.

For ease of description, spatially relational terms such as “below”, “under”, “lower”, “beneath”, “above”, and “upper” may be used herein for describing a relationship between one element or feature and another element or feature illustrated in the figure. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. The device may include other orientations (rotation by 90 degrees or in other orientations) and the spatial descriptors used herein may be interpreted accordingly.

The terms used herein are only intended to describe specific embodiments and are not a limitation to the disclosure. As used herein, singular forms “a/an”, “one”, and “the/said” may also be intended to include the plural forms, unless otherwise specified in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups may not be excluded. As used herein, the term “and/or” includes any and all combinations of the related listed items.

An anti-fuse array in some implementations contains four modules. Generally, a layout design engineer will design the layout structure of the anti-fuse array according to the direction of a signal flow of the anti-fuse array. However, this will cause the necessary distance between the modules in the layout structure of the anti-fuse array to be too large, resulting in a relatively large area of the layout structure of the anti-fuse array.

Before a layout structure of an anti-fuse array in the embodiment of the disclosure is described in detail, the working principle of the anti-fuse array and the layout structure of the anti-fuse array in some implementations are introduced at first.

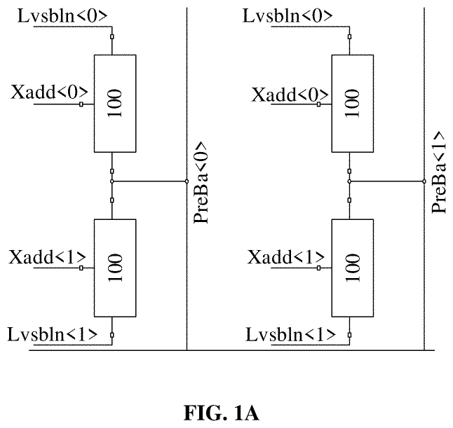

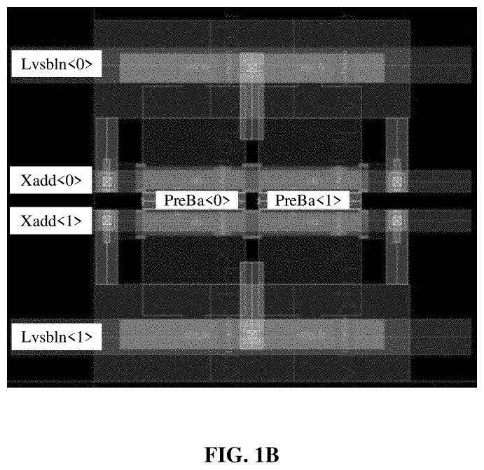

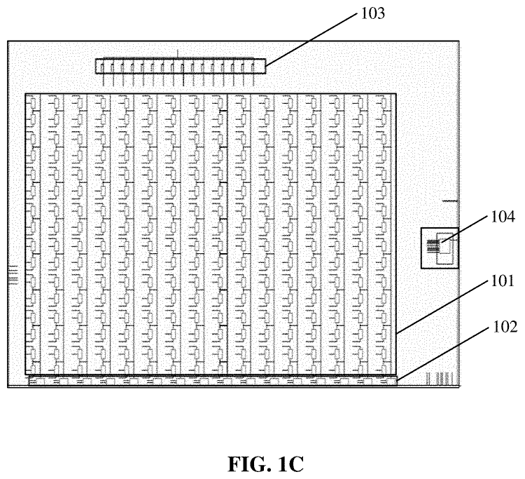

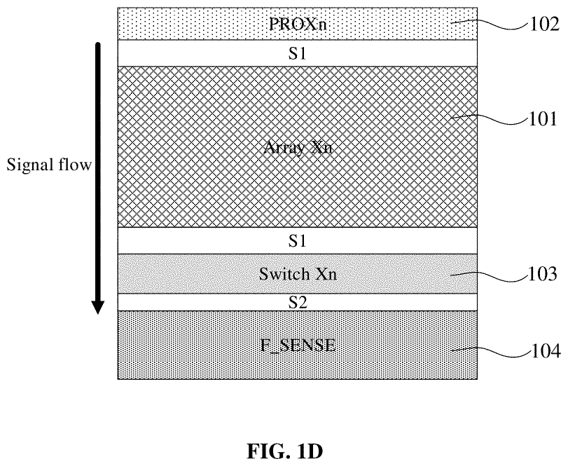

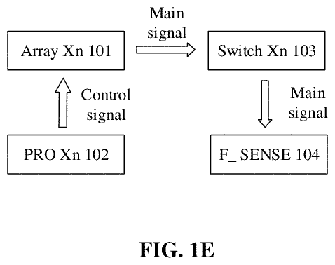

Hereinbelow, the anti-fuse array in some implementations including four anti-fuse cells is taken as an example for description. FIG. 1A is an optional circuit diagram of the anti-fuse array in some implementations, and FIG. 1B is an optional layout diagram of the anti-fuse array in some implementations. As illustrated in FIG. 1A and FIG. 1B, it can be seen that the anti-fuse array in some implementations is symmetrical in either up-down or left-right direction. The anti-fuse cell 100 includes two input ends Lvsb1n(*) and Xadd(*) and one output end PreBa(*), where * represents the number of a row or a column in the array, the Lvsb1n(*) is an input high-voltage signal, the Xadd(*) is an input control signal. Metal wires of the Lvsbln(*) and the Xadd(*) are connected to a gate through contact holes. The PreBa(*) is an output signal (connected to a bit line). The Lvsb1n(*) and the PreBa(*) may also be referred to as a word line row address (X_address) and a bit line column address (Y_address) respectively.

FIG. 1C is an optional circuit diagram of the anti-fuse array in some implementations. FIG. 1D is an optional schematic diagram of the layout structure of the anti-fuse array in some implementations. FIG. 1E is a schematic diagram of signal transmission of the anti-fuse array in some implementations. As illustrated in FIG. 1C—FIG. 1E, a circuit module of the anti-fuse array (Anti_fuse Xn) in some implementations includes four parts, which respectively are Array Xn 101, PRO Xn 102, Switch Xn 103 and F_SENSE 104. The Array Xn 101 is a high-voltage area, while the PRO Xn 102, the Switch Xn 103 and the F_SENSE 104 are low-voltage areas. It can be seen that, in the layout structure of the anti-fuse array in some implementations, the high-voltage area Array Xn 101 is located between two low-voltage areas. As illustrated in FIG. 1D, S1 represents a necessary distance from the high-voltage area to a low-voltage area, and S2 represents a necessary distance from a low-voltage area to another low-voltage area. Generally, S1 is greater than S2. Therefore, in the layout structure of the anti-fuse array in some implementations, the distance between the various modules is relatively large and is S1+S1+S2, resulting in a relatively large area of the layout structure of the anti-fuse array. It does not meet the requirements of miniaturization and high integration of a semiconductor device at present.

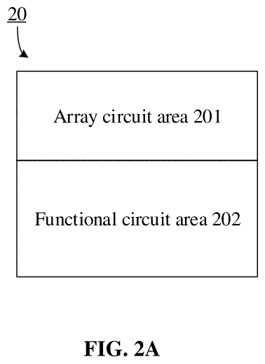

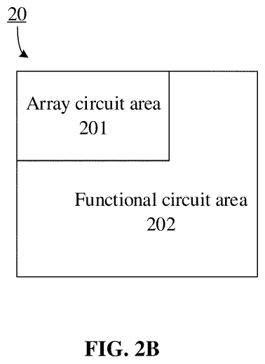

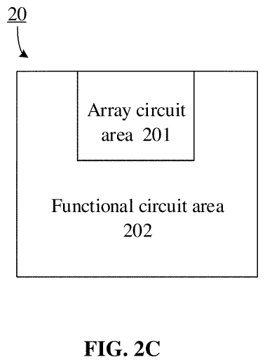

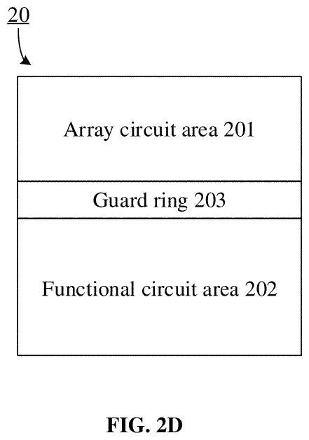

In view of the above problems in some implementations, the embodiment of the disclosure provides a layout structure of an anti-fuse array. FIGS. 2A—FIG. 2D are optional structural schematic diagrams of the layout structure of the anti-fuse array provided in the embodiment of the disclosure. As illustrated in FIGS. 2A—FIG. 2D, the layout structure 20 of the anti-fuse array at least includes an array circuit area 201 and a functional circuit area 202.

The array circuit area 201 is electrically connected with the functional circuit area 202. The functional circuit area 202 is located on at least one side of the array circuit area 201, and at least one side of the array circuit area 201 is located on the edge of the layout structure 20. As illustrated in FIG. 2A, the functional circuit area 202 is located on one side of the array circuit area, and three sides of the array circuit area 201 are located on the edge of the layout structure 20. As illustrated in FIG. 2B, the functional circuit area 202 is located on two sides of the array circuit area, and two sides of the array circuit area 201 are located on the edge of the layout structure 20. As illustrated in FIG. 2C, the functional circuit area 202 is located on three sides of the array circuit area, and one side of the array circuit area 201 is located on the edge of the layout structure 20.

The array circuit area 201 includes an anti-fuse array (not shown in the figure) composed of anti-fuse cells, and the array circuit area 201 is configured to provide the anti-fuse cells under different column addresses to the functional circuit area 202. In the embodiments of the disclosure, the anti-fuse array is composed of the anti-fuse cells under different row addresses and different column addresses.

The functional circuit area 202 is configured to fuse the anti-fuse cells under the different column addresses. In some embodiments, after the anti-fuse cells are fused, a storage function of the anti-fuse cells may be realized.

In the embodiments of the disclosure, since the array circuit area is composed of the anti-fuse array and the fusing of the anti-fuse cells in the anti-fuse array needs to be applied with high voltage, the array circuit area is a high-voltage area. Moreover, since the functional circuit area is usually composed of various types of transistors, the functional circuit area is a low-voltage area. In an actual configuration, the layout structure 20 also includes a guard ring 203 (as illustrated in FIG. 2D) located between the array circuit area and the functional circuit area. The guard ring 203 is configured to isolate signal crosstalk between the array circuit area (a high-voltage area) and the functional circuit area (a low-voltage area).

In the embodiments of the disclosure, since the layout structure of the anti-fuse array includes two modules, namely the array circuit area and the functional circuit area. Compared with some implementations, the number of modules is reduced, so that a necessary distance between the modules is also reduced. In this way, the area of the layout structure of the anti-fuse array is also reduced.

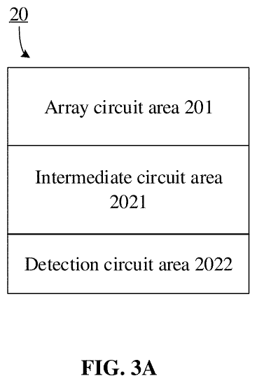

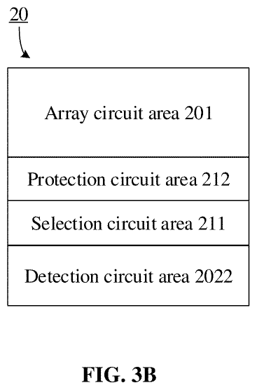

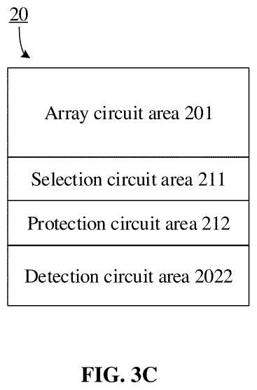

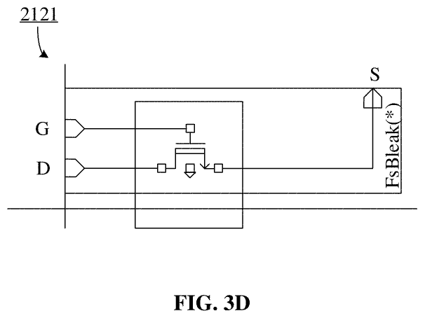

FIGS. 3A-3C are optional schematic diagrams of the layout structure of the anti-fuse array provided in the embodiments of the disclosure. In some embodiments, the functional circuit area includes an intermediate circuit area and a detection circuit area. As illustrated in FIG. 3A, the layout structure 20 of the anti-fuse array at least includes an array circuit area 201, an intermediate circuit area 2021 and a detection circuit area 2022.

The array circuit area 201 is electrically connected with the intermediate circuit area 2021, and the intermediate circuit area 2021 is electrically connected with the detection circuit area 2022.

In the embodiments of the disclosure, the intermediate circuit area 2021 is located between the array circuit area 201 and the detection circuit area 2022. The intermediate circuit area 201 is configured to fuse the anti-fuse cell under a specific column address in the anti-fuse array. The detection circuit area 2022 is located between the intermediate circuit area 2021 and an edge of the layout structure, and the detection circuit area 2022 is configured to detect an output value of the anti-fuse cell under the specific column address. Here, the output value may be a voltage value or a logic value.

In the embodiments of the disclosure, the array circuit area is a high-voltage area (the voltage is greater than 5 V), and the intermediate circuit area and the detection circuit area are low-voltage areas (the voltage is less than or equal to 5 V). Therefore, a guard ring (not shown in FIG. 3A) is also arranged between the array circuit area and the intermediate circuit area. The guard ring is configured to isolate signal crosstalk between the high-voltage area and the low-voltage area.

In some embodiments, the intermediate circuit area 2021 at least includes a selection circuit area. The selection circuit area is electrically connected with the array circuit area. The selection circuit area is configured to select an anti-fuse cell under the specific column address from the anti-fuse array for the fusing operation.

In some embodiments, the intermediate circuit area 2021 also includes a protection circuit area. The protection circuit area is electrically connected with the array circuit area and the selection circuit area, and the selection circuit area or the protection circuit area is electrically connected with the detection circuit area. The protection circuit area is configured to protect the anti-fuse cell not selected by the selection circuit area from being fused during the fusing operation.

As illustrated in FIG. 3B and FIG. 3C, the layout structure 20 of the anti-fuse array includes an array circuit area 201, a selection circuit area 211, a protection circuit area 212 and a detection circuit area 2022. Both the selection circuit area 211 and the protection circuit area 212 are electrically connected with the array circuit area 201. The selection circuit area 211 or the protection circuit area 212 is electrically connected with the detection circuit area 2022. That is, in the embodiments of the disclosure, the position of the selection circuit area 211 and the position of the protection circuit area 212 are interchangeable.

In some embodiments, the detection circuit area 2022 includes at least one Negative Channel Metal Oxide Semiconductor (NMOS) field-effect transistor, and an output end of the NMOS transistor is configured to output a detected output value of the anti-fuse cell under the specific column address.

In some embodiments, each anti-fuse cell in the anti-fuse array located in the array circuit area 201 at least includes a selection transistor, and each anti-fuse cell has two input ends. The anti-fuse cell under each column address in the anti-fuse array has a common output end. The two input ends are respectively configured to input a control signal and a high-voltage signal to a gate of the selection transistor.

In the embodiments of the disclosure, the two input ends of each anti-fuse cell are Lvsbln(*) and Xadd(*) respectively, where the Lvsbln(*) is configured to input a high-voltage signal, and the Xadd(*) is configured to input a control signal. The common output end of each column of anti-fuse cells is PreBa(*).

In some embodiments, the protection circuit area 212 includes a plurality of protection circuit units. An output end of each protection circuit unit is connected with an output end under a column address of the anti-fuse array. The output voltage at the output end of the protection circuit unit and the high-voltage signal are used to control the fusing of the anti-fuse cell under the corresponding column address.

In some embodiments, the output voltage of the protection circuit unit and the high-voltage signal are also used to control the anti-fuse cells under other column addresses from being fused.

FIG. 3D is a schematic structural diagram of a protection circuit unit provided in the embodiments of the disclosure. As illustrated in FIG. 3D, the protection circuit unit 2121 is a Positive Channel Metal Oxide Semiconductor (PMOS) field-effect transistor, and an output end FsBleak(*) of the protection circuit unit 2121 is a source end of the PMOS transistor.

Next, the working principle of the protection circuit will be described.

Since the output end FsBleak(*) of each protection circuit unit is connected with an output end PreBa(*) under a column address of the anti-fuse array, the PreBa(*) (i.e., a bit line) under the corresponding column address may be charged to a certain voltage through the protection circuit unit. Base on the working principle of the anti-fuse cell, it can be known that an input end Lvsbln(*) of the target anti-fuse cell needs to be applied with high voltage, if a selected target anti-fuse cell is desired to be fused. When a certain voltage difference between the input end Lvsbln(*) and the output end PreBa(*) of the target anti-fuse cell is reached, the target anti-fuse cell will be fused (short-circuited). However, the unselected anti-fuse cell will also have the risk of fusing, since the input end Lvsbln(*) of the target anti-fuse is applied with high voltage. Therefore, it is necessary to charge the output ends of other anti-fuse cells to a certain high potential through each protection circuit unit in the protection circuit, so as to prevent the unselected anti-fuse cell from being fused due to an excessive voltage difference between the input end and the output end thereof. During the fusing, a signal of the output end PreBa(*) under the target column address of the anti-fuse array is adjusted to be a low potential through the selection circuit and the detection circuit.

In some embodiments, the selection circuit area 2022 includes a plurality of selection circuit units. Through the connection between the selection circuit unit and an output end under a column address of the anti-fuse array, the anti-fuse cell under the specific column address is selected. The selection circuit unit includes at least one PMOS transistor.

In some embodiments, the array circuit area 201 is connected to a first metal layer M0 through a contact hole to transmit an output signal of the array circuit area at least through the first metal layer M0.

In some embodiments, a gate of the selection transistor is connected to two parallel second metal layers M1 respectively through contact holes to respectively provide the high-voltage signal and the control signal to the gate at least through the two parallel second metal layers M1.

Here, the widths of the two second metal layers M1 connected with the gate are different. The second metal layer for providing the high-voltage signal has a first preset width, and the second metal layer for providing the control signal has a second preset width. Here, the first preset width is greater than the second preset width. For example, the first preset width may be 0.5 μm, and the second preset width may be 0.3 μm.

In some embodiments, the detection circuit area is connected to a third metal layer M2 through a contact hole to transmit an output signal of the detection circuit area at least through the third metal layer M2. The third metal layer is parallel to the first metal layer, and the third metal layer is perpendicular to the second metal layers.

In the embodiment of the disclosure, other metal layers are also arranged above the third metal layer, such as a fourth metal layer and a fifth metal layer. It is to be noted that, the metal layers are respectively arranged alternately along different directions. For example, the first metal layer, the third metal layer and the fifth metal layer are arranged horizontally, and the second metal layers and the fourth metal layer are arranged vertically.

The layout structure of the anti-fuse array provided in the embodiments of the disclosure includes the array circuit area, the intermediate circuit area and the detection circuit area. Since the protection circuit area and selection circuit area constituting the intermediate circuit area are composed of the PMOS transistors and the detection circuit area is the NMOS transistor, the area of the whole module can be saved in the layout structure design, and the quality of the whole module can be improved during manufacturing a chip, since the same type of Metal Oxide Semiconductor (MOS) field effect transistors are arranged together.

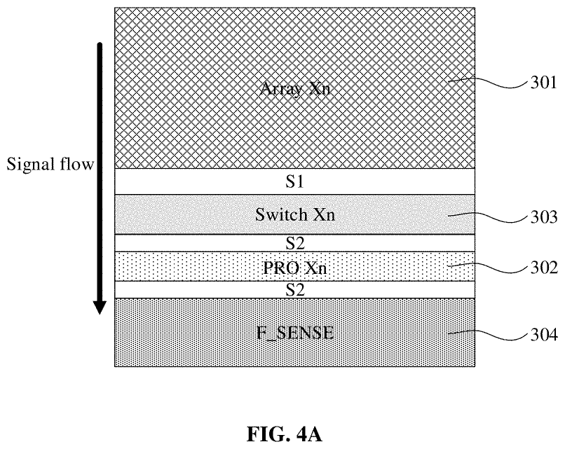

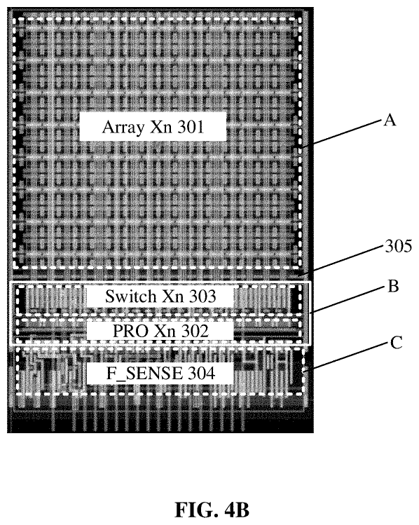

FIG. 4A and FIG. 4B are other optional schematic diagrams of the layout structure of the anti-fuse array provided in an embodiment of the disclosure. As illustrated in FIG. 4A, the layout structure 30 of the anti-fuse array includes: Array Xn 301 (corresponding to the array circuit area in the above embodiment), PRO Xn 302 (corresponding to the protection circuit area in the above embodiment), Switch Xn 303 (corresponding to the selection circuit area in the above embodiment), F_SENSE 304 (corresponding to the detection circuit area in the above embodiment) and a guard ring 305.

The Array Xn 301 is configured to provide anti-fuse cells under different column addresses to the Switch Xn 303. The Switch Xn 303 is configured to select an anti-fuse cell under the specific column address from the anti-fuse array for the fusing operation, that is, the Switch Xn 303 is a transmission module for controlling Y_address. The PRO Xn 302 is configured to protect the anti-fuse cells not selected by the selection circuit area from being fused during the fusing operation, that is, the PRO Xn 302 is a circuit module for protecting the anti-fuse cells from being broken down. The F_SENSE 304 is configured to detect an output value of the anti-fuse cell under the specific column address, that is, the F_SENSE 304 is a circuit module for detecting and processing the output Y_address.

In the embodiment of the disclosure, the Array Xn 301 is electrically connected with the PRO Xn 302 and the Switch Xn 303 respectively. The PRO Xn 302 is located between the Array Xn 301 and the Switch Xn 303, and the F_SENSE 304 is electrically connected with the Switch Xn 303. Since the F_SENSE 304 is also used to be connected to other circuit structures, the F_SENSE 304 is generally arranged on the edge of the layout structure.

A direction of a signal flow of the various modules in the layout structure of the anti-fuse array provided in the embodiment of the disclosure is as follows. The PRO Xn 302 provides a control signal to the Array Xn 301, the Array Xn 301 provides a main signal to the Switch Xn 303, and the Switch Xn 303 provides the main signal to the F_SENSE 304.

In the embodiment of the disclosure, the Array Xn 301 is a high-voltage area while the PRO Xn 302, the Switch Xn 303 and the F_SENSE 304 are low-voltage areas, and the guard ring 305 is located between the Array Xn 301 and the PRO Xn 302, the Switch Xn 303 and the F_SENSE 304, and is configured to isolate the high-voltage area from the low-voltage area to avoid signal crosstalk between the high-voltage area and the low-voltage area.

In the embodiment of the disclosure, an output signal of the Array Xn 301 is transmitted at least through the first metal layer M0. The high-voltage signal and control signal required by each anti-fuse cell in the Array Xn 301 are transmitted at least through the two mutually parallel second metal layers M1. An output signal of the F_SENSE 304 is transmitted at least through the third metal layer M2. The arrangement direction of the second metal layers is perpendicular to that of the first metal layer, the third metal layer is parallel to the first metal layer, and the third metal layer is perpendicular to the second metal layers.

Also referring to FIG. 4B, in some embodiments, both the PRO Xn 302 and the Switch Xn 303 are formed by PMOS transistors, and the F_SENSE 304 is formed by NMOS transistors. Therefore, the layout structure of the anti-fuse array in the embodiment of the disclosure may be divided into three areas according to the type of the MOS transistors, namely an Array Xn area A, a PMOS area B and an NMOS area C. In the layout structure design, the area of the whole module can be saved, by arranging the same type of MOS transistors together. During manufacturing a chip, the quality of the whole module can be improved, by arranging the same type of MOS transistors together.

Also referring to FIG. 4A, S1 represents a necessary distance from the high-voltage area to the low-voltage area, and S2 represents a necessary distance from the low-voltage area to the low-voltage area. Generally, S1 is greater than S2. Therefore, in the layout structure of the anti-fuse array in the embodiment of the disclosure, the distance between the various modules is S1+S2+S2. Compared with the distance S1+S1+S2 between the various modules in the layout structure of the anti-fuse array in some implementations, the distance between the various modules in the layout structure of the anti-fuse array in the embodiment of the disclosure is reduced. As a result, the area of the layout structure of the anti-fuse array in the embodiment of the disclosure is also reduced, which meets the requirements of miniaturization and high integration of a semiconductor device at present.

In terms of modules, the layout structure of the anti-fuse array provided by the embodiment of the disclosure may be divided into four small modules, namely Array Xn, switch Xn, PRO Xn and F-FENSE. These four small modules may be matched with the modules of the whole circuit to realize the function of the anti-fuse array.

In the several embodiments provided in the disclosure, it should be understood that, the disclosed devices and methods may be realized in a non-target manner. The device embodiment described above is illustrative. For example, division of the units is only a logic function division, and other division manners may be adopted during practical implementation. For example, a plurality of units or components may be combined or integrated into another system, or some features may be neglected or not executed. In addition, the components shown or discussed are coupled, or directly coupled to each other.

The above-mentioned units described as separate parts may be or may not be physically separate, and the parts shown as units may be or may not be physical units, which may be located in one place or distributed to a plurality of network elements. Part or all of the units may be selected to achieve the objectives of the solutions of the embodiments according to practical requirements.

The features disclosed in the several method or device embodiments provided by the disclosure may be combined arbitrarily unless conflicted, to obtain new method embodiments or device embodiments.

The above are only some implementation modes of the embodiments of the disclosure and not intended to limit the scope of protection of the embodiments of the disclosure. Those skilled in the art can make modifications or replacements within the technical scope disclosed by the embodiments of the disclosure, and these modifications or replacements shall fall within the scope of protection of the embodiments of the disclosure. Therefore, the scope of protection of the embodiments of the disclosure should only be interpreted by the appended claims.

What is claimed is:

1. A layout structure of an anti-fuse array, at least comprising an array circuit area and a functional circuit area, wherein:
the array circuit area is electrically connected with the functional circuit area; the functional circuit area is located on at least one side of the array circuit area; at least one side of the array circuit area is located on an edge of the layout structure;
the array circuit area comprises an anti-fuse array composed of anti-fuse cells; the array circuit area is configured to provide the anti-fuse cells under different column addresses to the functional circuit area; and
the functional circuit area is configured to fuse the anti-fuse cells under the different column addresses.

2. The layout structure according to claim 1, wherein:
the functional circuit area comprises an intermediate circuit area and a detection circuit area;
the array circuit area is electrically connected with the intermediate circuit area; and the intermediate circuit area is electrically connected with the detection circuit area;
the intermediate circuit area is located between the array circuit area and the detection circuit area; the intermediate circuit area is configured to fuse an anti-fuse cell under a specific column address in the anti-fuse array;
the detection circuit area is located between the intermediate circuit area and an edge of the layout structure; and the detection circuit area is configured to detect an output value of the anti-fuse cell under the specific column address.

3. The layout structure according to claim 2, wherein:
the intermediate circuit area at least comprises a selection circuit area;
the selection circuit area is electrically connected with the array circuit area; and
the selection circuit area is configured to select the anti-fuse cell under the specific column address from the anti-fuse array for the fusing.

4. The layout structure according to claim 3, wherein:
the intermediate circuit area further comprises a protection circuit area;
the protection circuit area is electrically connected with the array circuit area and the selection circuit area; the selection circuit area or the protection circuit area is electrically connected with the detection circuit area; and
the protection circuit area is configured to protect the anti-fuse cell not selected by the selection circuit area from being fused during the fusing.

5. The layout structure according to claim 1, further comprising a guard ring located between the array circuit area and the functional circuit area, wherein:
the guard ring is configured to isolate signal crosstalk between the array circuit area and the functional circuit area.

6. The layout structure according to claim 2, wherein
the detection circuit area comprises at least one Negative Channel Metal Oxide Semiconductor (NMOS) transistor; and
an output end of the NMOS transistor is configured to output a detected output value of the anti-fuse cell under the specific column address.

7. The layout structure according to claim 1, wherein:
each of the anti-fuse cells in the anti-fuse array at least comprises a selection transistor; each of the anti-fuse cells has two input ends; the anti-fuse cells under each column address in the anti-fuse array has a common output end; and
the two input ends are respectively configured to input a control signal and a high-voltage signal to a gate of the selection transistor.

8. The layout structure according to claim 7, wherein:
the protection circuit area comprises a plurality of protection circuit units; and
an output end of each of the protection circuit units is connected with an output end under a column address of the anti-fuse array; and an output voltage at the output end of the protection circuit unit and the high-voltage signal are used to control the fusing of an anti-fuse cell under a corresponding column address.

9. The layout structure according to claim 8, wherein the output voltage of the protection circuit unit and the high-voltage signal are further used to control anti-fuse cells under other column addresses from being fused.

10. The layout structure according to claim 8, wherein:
each of the protection circuit units comprises a Positive Channel Metal Oxide Semiconductor (PMOS) transistor; and
the output end of the protection circuit unit is a source end of the PMOS transistor.

11. The layout structure according to claim 7, wherein:
the selection circuit area comprises a plurality of selection circuit units; and
through connection between the selection circuit unit and an output end under a column address of the anti-fuse array, the anti-fuse cell under the specific column address is selected.

12. The layout structure according to claim 11, wherein each of the selection circuit units comprises at least one PMOS transistor.

13. The layout structure according to claim 7, wherein the array circuit area is connected to a first metal layer through a contact hole to transmit an output signal of the array circuit area at least through the first metal layer.

14. The layout structure according to claim 13, wherein:
the gate of the selection transistor is connected to two parallel second metal layers respectively through contact holes to provide the high-voltage signal and the control signal respectively to the gate at least through the two parallel second metal layers; and
an arrangement direction of the second metal layers is perpendicular to that of the first metal layer.

15. The layout structure according to claim 14, wherein:
the detection circuit area is connected to a third metal layer through a contact hole to transmit an output signal of the detection circuit area at least through the third metal layer;
wherein the third metal layer is parallel to the first metal layer, and the third metal layer is perpendicular to the second metal layers.
